(19) United States
(12) Patent Application Publication
(10) Pub. No.: US 2018/0048267 A1
(43) Pub. Date: Feb. 15, 2018

(54) AMPLIFICATION DEVICE AND METHOD OF AMPLIFYING SIGNAL

(71) Applicant: FUJITSU LIMITED, Kawasaki-shi (JP)

(72) Inventor: Yuichi UTSUNOMIYA, Kawasaki (JP)

(73) Assignee: FUJITSU LIMITED, Kawasaki-shi (JP)

(21) Appl. No.: 15/656,746

(22) Filed: Jul. 21, 2017

(30) Foreign Application Priority Data
Aug. 9, 2016 (JP) 2016-156999

(51) Int. Cl. H03F 1/32; H03F 3/20; H03F 1/02

(52) U.S. Cl. CPC H03F 1/32; H03F 1/0288; H03F 3/20; H03F 2201/3212; H03F 2201/3233; H03F 2201/3215

(57) ABSTRACT

An amplification device that amplifies two signals split from an input signal and synthesizes the amplified signals, the amplification device includes a first adjuster that adjusts a phase difference between the two signals by using power of an output signal acquired by synthesizing the two signals, and a second adjuster that adjusts phases of the two signals by using an Amplitude Modulation (AM)-Phase Modulation (PM) characteristic that indicates a relationship between the power of the input signal and the phase of the output signal in a state of fixing the phase difference adjusted by the first adjuster.

### CROSS-REFERENCE TO RELATED APPLICATION

This application is based upon and claims the benefit of priority of the prior Japanese Patent Application No. 2016-156999, filed on Aug. 9, 2016, the entire contents of which are incorporated herein by reference.

### FIELD

The embodiments discussed herein are related to an amplification device and a method of amplifying a signal.

### BACKGROUND

In the related art, an amplification device has been used for amplifying the transmission power in various electronic apparatuses including a base station of a mobile communication system. Particularly, in recent years, with an increase in communication speed, it is expected to amplify the transmission power with higher efficiency from the viewpoint of suppressing power consumption, and the like. It is known that the efficiency of an amplification device is highest in an output saturation state (non-linear state) and a Doherty type amplification device (hereinafter, referred to as “Doherty amplification device”) is proposed as an amplification device corresponding thereto.

The Doherty amplification device includes a Carrier Amplifier (CA) and a Peak Amplifier (PA) connected in parallel, and the CA and the PA operate sequentially as input power increases. In addition, the Doherty amplification device separates an input signal into two signals, amplifies two signals by the CA and the PA, respectively, and synthesizes two amplified signals.

Herein, it is known that an amplification efficiency of the Doherty amplification device varies depending on a phase difference between two signals separated from the input signal, that is, the phase difference between two signals input to the CA and the PA.

Therefore, in order to improve the amplification efficiency of the Doherty amplification device, an adjusting of the phase difference between two signals input to the CA and the PA may be considered so as to maximize power of an output signal using the power of the output signal of the Doherty amplification device, which is obtained by combining two signals. However, when the phase difference between two signals input to the CA and the PA is adjusted, a non-linearity of an Amplitude Modulation (AM)-Phase Modulation (PM) characteristic indicating a relationship between the power of the input signal and a phase of the output signal increases and the output signal is distorted.

The following is a reference document.

### [Document 1] Japanese Laid-Open Patent Publication No. 2002-124840.

### SUMMARY

According to an aspect of the embodiments, an amplification device that amplifies two signals split from an input signal and synthesizes the amplified signals, the amplification device includes a first adjuster that adjusts a phase difference between the two signals by using power of an output signal acquired by synthesizing the two signals, and a second adjuster that adjusts phases of the two signals by using an Amplitude Modulation (AM)-Phase Modulation (PM) characteristic that indicates a relationship between the power of the input signal and the phase of the output signal in a state of fixing the phase difference adjusted by the first adjuster. The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a block diagram illustrating a configuration of an amplification device according to a first embodiment;

FIG. 2 is a diagram illustrating one example of a first adjustment table stored in a memory according to the first embodiment;

FIG. 3 is a diagram illustrating one example of a second adjustment table stored in the memory according to the first embodiment;

FIG. 4 is a diagram illustrating examples of first phase adjustment processing and second phase adjustment processing according to the first embodiment;

FIG. 5 is a diagram illustrating a detailed example of the second phase adjustment processing according to the first embodiment;

FIG. 6 is a diagram illustrating one example of a second adjustment table after the second phase adjustment processing is performed according to the first embodiment;

FIG. 7 is a flowchart illustrating one example of the first phase adjustment processing according to the first embodiment;

FIG. 8 is a flowchart illustrating one example of the second phase adjustment processing according to the first embodiment;

FIG. 9 is a diagram illustrating a detailed example of second phase adjustment processing according to a second embodiment;

FIG. 10 is a diagram illustrating one example of a second adjustment table after the second phase adjustment processing is performed according to the second embodiment;

FIG. 11 is a flowchart illustrating one example of the second phase adjustment processing according to the second embodiment;

FIG. 12 is a diagram illustrating a detailed example of second phase adjustment processing according to a third embodiment;

FIG. 13 is a block diagram illustrating a configuration of an amplification device according to a fourth embodiment;

FIG. 14 is a flowchart illustrating one example of second phase adjustment processing according to the fourth embodiment; and

FIG. 15 is a block diagram illustrating a configuration of an amplification device according to a modified example.

### DESCRIPTION OF EMBODIMENTS

Hereinafter, embodiments of an amplification device of the present disclosure will be described in detail with reference to the accompanying drawings. Further, the embodiments are not limited to a technology disclosed herein. In addition, in the embodiments, the same reference numerals are given to the same components having the same functions, and redundant descriptions thereof will be omitted.

### First Embodiment

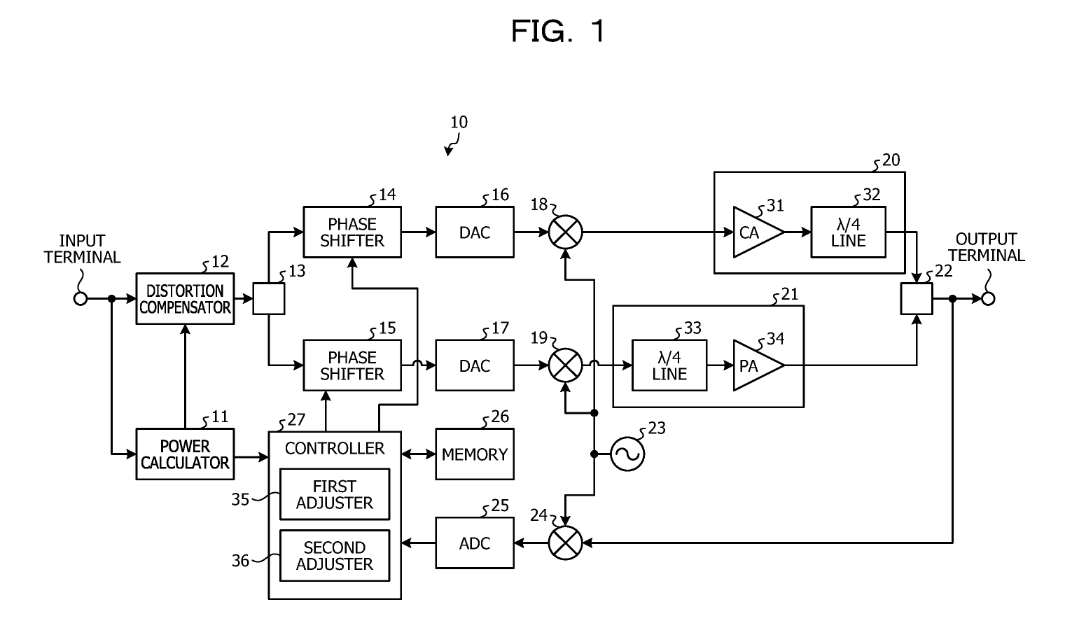

FIG. 1 is a block diagram illustrating a configuration of an amplification device 10 according to the first embodiment. As illustrated in FIG. 1, the amplification device 10 includes a power calculator 11, a distortion compensator 12, a signal splitter 13, phase shifters 14 and 15, digital-analog converters (DACs) 16 and 17, frequency converters 18 and 19, amplifiers 20 and 21, and a synthesizer 22. Further, the amplification device 10 includes a reference carrier generator 23, a frequency converter 24, an analog-digital converter (ADC) 25, a memory 26, and a controller 27. Further, the amplification device 10 is a Doherty type amplification device.

The power calculator 11 calculates power of an input signal input from an input terminal and outputs the calculated power of the input signal to the distortion compensator 12 and the controller 27.

The distortion compensator 12 performs distortion compensation processing of the input signal. For example, the distortion compensator 12 keeps a look up table (LUT) storing a distortion compensation coefficient, reads the distortion compensation coefficient from the LUT by using the power of the input signal as an address, multiplies the input signal by the read distortion compensation coefficient, and outputs the input signal after the distortion compensation processing.

The signal splitter 13 splits the input signal input from the distortion compensator 12 into two signals, and outputs one of the two signals to a system of the amplifier 20 and outputs the other one to the system of the amplifier 21. Hereinafter, the signal output to the system of the amplifier 20 from the signal splitter 13 is referred to as “first signal” and the signal output to the system of the amplifier 21 from the signal splitter 13 is referred to as “second signal.”

The phase shifter 14 adjusts a phase of the first signal according to a control by the controller 27. The phase shifter 15 adjusts the phase of the second signal according to the control by the controller 27.

The DAC 16 digital-analog converts the first signal and outputs the acquired analog first signal to the frequency converter 18. The DAC 17 digital-analog converts the second signal and outputs the acquired analog second signal to the frequency converter 19.

The frequency converter 18 frequency-converts the first signal by using a reference carrier generated by the reference carrier generator 23 and outputs the first signal after the frequency conversion to the amplifier 20. The frequency converter 19 frequency-converts the second signal by using the reference carrier generated by the reference carrier generator 23 and outputs the second signal after the frequency conversion to the amplifier 21.

The amplifier 20 includes a CA 31 and a λ/4 line 32. The CA 31 is an amplifier having linearity when the input power is smaller than a predetermined value and amplifies the first signal. The λ/4 line 32 is connected to an output terminal of the CA 31 and converts output-side impedance of the CA 31.

The amplifier 21 includes a λ/4 line 33 and a PA 34. The λ/4 line 33 is a line for compensating a phase difference between the CA 31 and the PA 34, which is caused from the λ/4 line 32 connected to the output terminal of the CA 31. The PA 34 is an amplifier which is turned on only when the input power is equal to or larger than the predetermined value and amplifies the second signal.

The synthesizer 22 synthesizes the signal output from the amplifier 20 and the signal output from the amplifier 21 and outputs an output signal acquired by the synthesis to an output terminal. Further, a part of the output signal output to the output terminal from the synthesizer 22 is fed back to the frequency converter 24 as a feedback signal.

The reference carrier generator 23 generates the reference carrier and outputs the generated reference carrier to the frequency converter 18, the frequency converter 19, and the frequency converter 24.

The frequency converter 24 frequency-converts the output signal fed back from the synthesizer 22 as the feedback signal by using the reference carrier generated by the reference carrier generator 23 and outputs the output signal after the frequency conversion to the ADC 25.

The ADC 25 analog-digital converts the output signal input from the frequency converter 24 and outputs the acquired digital output signal to the controller 27.

The memory 26 stores a first adjustment table used for “first phase adjustment processing” to adjust the phase difference between the first and second signals and a second adjustment table used for “second phase adjustment processing” to adjust the phases of the first and second signals. Hereinafter, the phase of the first signal is referred to as “CA phase” and the phase of the second signal is referred to as “PA phase.”

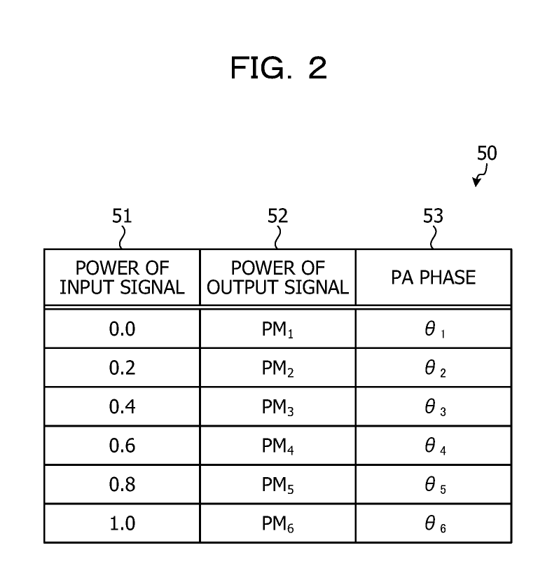

FIG. 2 is a diagram illustrating one example of a first adjustment table stored in a memory 26 according to the first embodiment. Power 52 and a PA phase 53 of the output signal are stored in a first adjustment table 50 illustrated in FIG. 2 to correspond to power 51 of the input signal. The power 51 of the input signal is a normalized value.

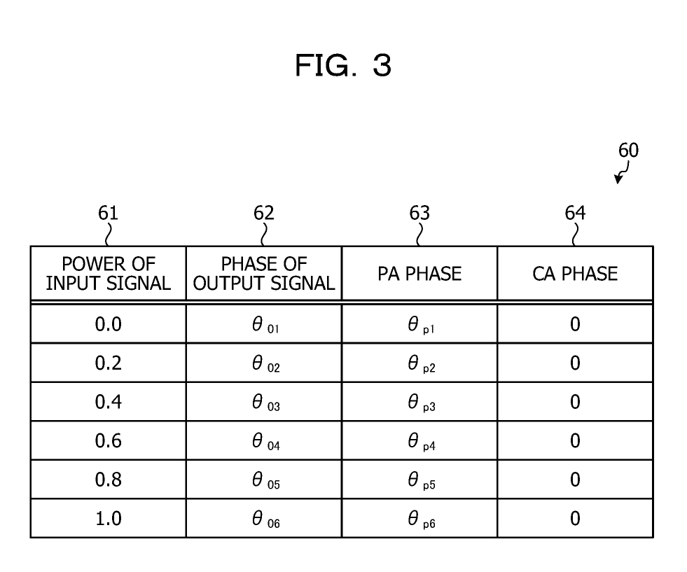

FIG. 3 is a diagram illustrating one example of a second adjustment table stored in the memory 26 according to the first embodiment. A phase 62, a PA phase 63, and a CA phase 64 of the output signal are stored in the second adjustment table 60 illustrated in FIG. 3 to correspond to power 61 of the input signal. A relationship between the power 61 of the input signal and the phase 62 of the output signal corresponds to an amplitude modulation (AM)-phase modulation (PM) characteristic of the amplification device 10. The power 61 of the input signal is the normalized value. The PA phase 63 corresponds to the PA phase 53 of the first adjustment table 50.

The controller 27 includes a first adjuster 35 and a second adjuster 36.

The first adjuster 35 performs the first phase adjustment processing by controlling the phase shifter 15. That is, the first adjuster 35 calculates the power of the output signal input from the ADC 25 and adjusts the phase difference between the first signal and the second signal by using the calculated power of the output signal. For example, the first adjuster 35 adjusts the phase difference between the first signal and the second signal by changing the PA phase so as to maximize the power of the output signal to the power of the input signal by referring to the first adjustment table in the memory 26.

The second adjuster 36 performs the second phase adjustment processing by controlling the phase shifters 14 and 15 after the first phase adjustment processing is performed. That is, the second adjuster 36 adjusts the phases of the first and second signals by using the AM-PM characteristic indicating the relationship between the power of the input signal and the phase of the output signal while fixing the phase difference between the first and second signals, which is adjusted by the first adjuster 35. For example, the second adjuster 36 adjusts the CA phase and the PA phase so that the phase of the output signal in the AM-PM characteristic is close to a predetermined value by referring to the second adjustment table in the memory 26.

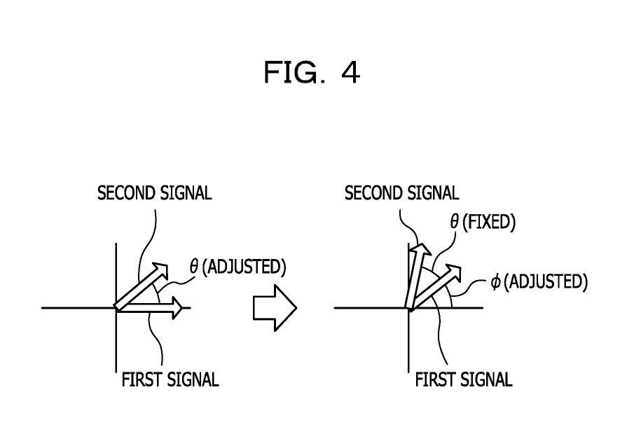

FIG. 4 is a diagram illustrating examples of first phase adjustment processing and second phase adjustment processing according to the first embodiment. For example, the first adjuster 35 adjusts a phase difference θ between the first signal and the second signal so as to maximize the power of the output signal to the power of the input signal as illustrated at a left side of FIG. 4. In addition, the second adjuster 36 adjusts phases φ of the first and second signals so that the phase of the output signal in the AM-PM characteristic is close to a predetermined value while fixing the phase difference θ adjusted by the first adjuster 35 as illustrated at a right side of FIG. 4.

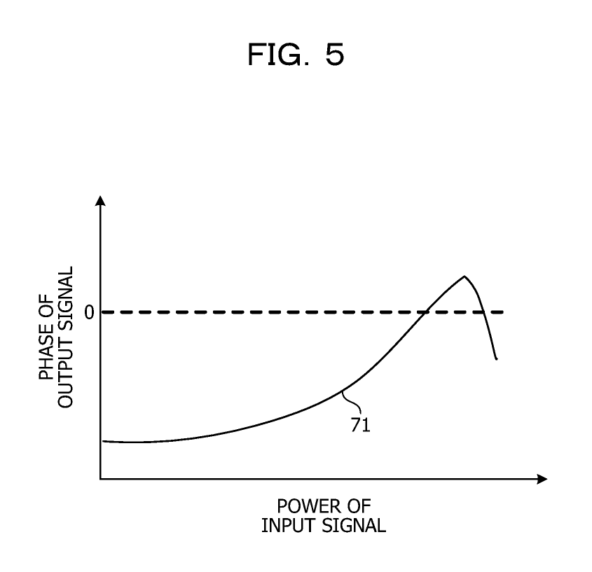

FIG. 5 is a diagram illustrating a detailed example of the second phase adjustment processing according to the first embodiment. In FIG. 5, the AM-PM characteristic indicating the relationship between the power of the input signal and the phase of the output signal is expressed by a curved line 71. As illustrated in FIG. 5, the second adjuster 36, for example, adjusts the phases φ of the first and second signals so that the phase of the output signal in the AM-PM characteristic is close to “0” which is a predetermined value. Further, the predetermined value is not limited to “0” and may be a value other than “0.”

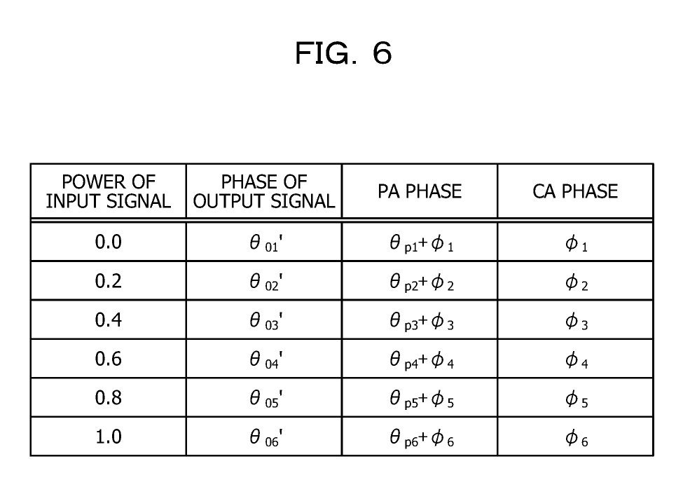

FIG. 6 is a diagram illustrating one example of a second adjustment table after the second phase adjustment processing is performed according to the first embodiment. Herein, the first phase adjustment processing is performed, and as a result, the PA phase is changed to θₚ₁ to θₚ₆ with respect to the power of each input signal (see FIG. 3). In other words, the first phase adjustment processing is performed, and as a result, the phase difference between the first signal and the second signal is changed to θₚ₁ to θₚ₆ so as to maximize the power of the output signal to the power of each input signal. The first phase adjustment processing is performed and thereafter, the second phase adjustment processing is performed. That is, while the phase difference between the first signal and the second signal is fixed to θₚ₁ to θₚ₆, the phases of the first and second signals are adjusted so that the phase of the output signal in the AM-PM characteristic is close to “0” which is the predetermined value. As a result, as illustrated in FIG. 6, while the phase difference between the first signal and the second signal is fixed to θₚ₁ to θₚ₆, the PA phase and the CA phase are adjusted as large as φ₁ to φ₆ with respect to the power of each input signal.

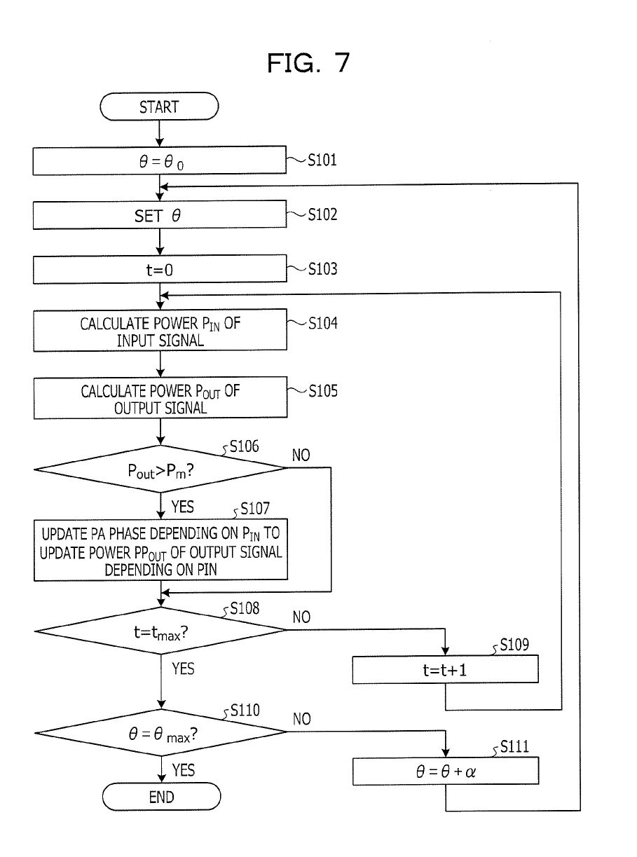

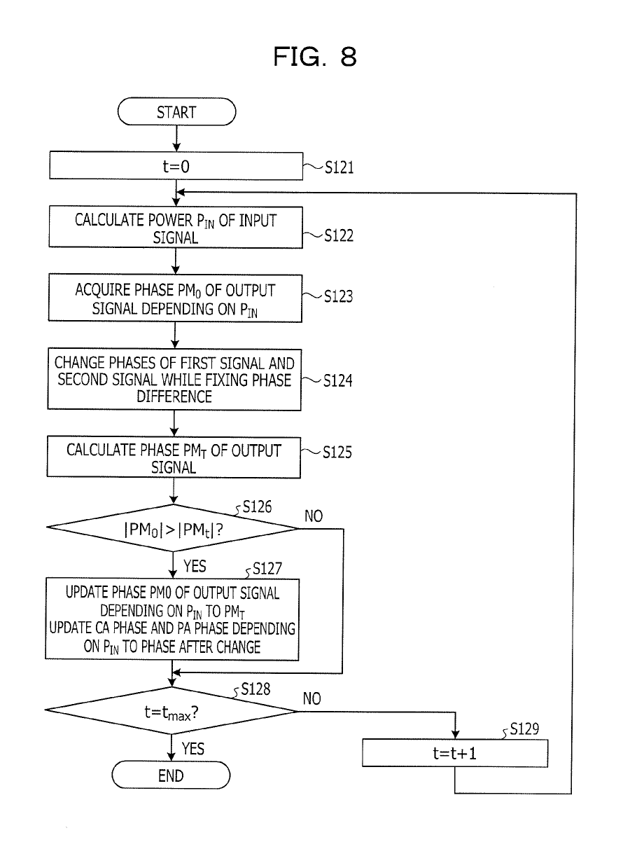

Next, the first phase adjustment processing and the second phase adjustment processing in the amplification device 10 configured as such will be exemplified in detail with reference to FIGS. 7 and 8. FIG. 7 is a flowchart illustrating one example of the first phase adjustment processing according to the first embodiment. The first phase adjustment processing illustrated in FIG. 7 is executed primarily by the first adjuster 35.

As illustrated in FIG. 7, an initial value θ₀ is set in a parameter θ for changing (adjusting) the PA phase (S101). For example, when the PA phase is changed to a plurality of change values which exist in a predetermined range, the initial value θ₀ is a smallest change value among the plurality of change values. The first adjuster 35 sets the parameter θ as the phase of the second signal by controlling the phase shifter 15 (S102).

When an input signal of a time t=0 is input with respect to the amplification device 10 (S103), power Pᵢₙ of the input signal is calculated by the power calculator 11 (S104) and power Pₒᵤₜ of the output signal is calculated by the first adjuster 35 (S105).

The first adjuster 35 acquires power Pₘ of the output signal according to the power Pᵢₙ of the input signal by referring to the first adjustment table in the memory 26. The power of the output signal, which is calculated by the first adjuster 35, is stored in the first adjustment table in the memory 26 as the power Pₘ of the output signal with respect to an initial value of power of a predetermined output signal or another parameter θ. The first adjuster 35 determines whether the power (that is, the power Pₒᵤₜ of the output signal, which is calculated in step S105) of the output signal, which is calculated with respect to the current parameter θ, is larger than the power Pₘ of the output signal, which is acquired from the first adjustment table in the memory 26 (S106).

The first adjuster 35 refers to the first adjustment table in the memory 26 when it is determined that the power Pₒᵤₜ of the output signal, which is calculated in step S105, is larger than the power Pₘ of the output signal, which is acquired from the first adjustment table in the memory 26 (“Yes” in S106). In addition, the first adjuster 35 updates the PA phase depending on the power Pᵢₙ of the input signal to the parameter θ and updates the power Pₘ of the output signal depending on the power Pᵢₙ of the input signal to the power Pₒᵤₜ of the output signal, which is calculated in step S105 (S107).

Meanwhile, the first adjuster 35 advances the processing to step S108 without updating the first adjustment table in the memory 26 when the power Pₒᵤₜ of the output signal, which is calculated in step S105, is equal to or smaller than the power Pₘ of the output signal, which is acquired from the first adjustment table in the memory 26 (No in S106).

When it is determined that an input signal of a time t=tₘₐₓ is not input with respect to the amplification device 10 (“No” in S108), the time t is incremented by 1 (S109) and the processing of each of steps S104 to S108 is repeatedly executed. Herein, tₘₐₓ represents a maximum value of a predetermined time t.

When it is determined that the input signal of the time t=tₘₐₓ is input with respect to the amplification device 10 (“Yes” in S108), the first adjuster 35 determines whether the parameter θ reaches a maximum value θₘₐₓ of the predetermined parameter θ (S110). When the parameter θ is changed to a plurality of change values which exist in a predetermined range, the maximum value θₘₐₓ of the parameter θ is the largest change value among the plurality of change values.

When it is determined that the parameter θ does not reach the maximum value θₘₐₓ (“No” in S110), the first adjuster 35 increases the parameter θ as large as a change width a (S111) and returns the processing to step S102. As a result, in step S102, the first adjuster 35 sequentially changes the phase of the second signal to the plurality of change values which exist in the predetermined range. In addition, until the parameter θ reaches the maximum value θₘₐₓ, the processing of each of steps S103 to S110 is repeatedly executed. As a result, the PA phase is changed and the phase difference between the first signal and the second signal is adjusted so as to maximize the power Pₒᵤₜ of the output signal to the power Pᵢₙ of the input signal.

When it is determined that the parameter θ reaches the maximum value θₘₐₓ (“Yes” in S110), the first adjuster 35 ends the first phase adjustment processing.

FIG. 8 is a flowchart illustrating one example of the second phase adjustment processing according to the first embodiment. The second phase adjustment processing illustrated in FIG. 8 is executed primarily by the second adjuster 36 after the first phase adjustment processing illustrated in FIG. 7 is performed. Further, it is assumed that the first phase adjustment processing illustrated in FIG. 7 is performed, and as a result, the phase of the output signal when the power Pₒᵤₜ of the output signal to the power Pᵢₙ of the input signal becomes the maximum and the PA phase are stored in the second adjustment table in the memory 26.

As illustrated in FIG. 8, when the input signal of the time t=0 is input with respect to the amplification device 10 (S121), the power calculator 11 calculates the power Pᵢₙ of the input signal (S122).

The second adjuster 36 acquires a phase PM₀ of the output signal depending on the power Pᵢₙ of the input signal by referring to the second adjustment table in the memory 26 (S123). The phase of the output signal when the power Pₒᵤₜ of the output signal to the power Pᵢₙ of the input signal becomes the maximum is prestored in the second adjustment table in the memory 26 as the phase PM₀ of the output signal.

The second adjuster 36 changes the phases of the first and second signals by controlling the phase shifters 14 and 15 while fixing the phase difference between the first and second signals, which is adjusted by the first adjuster 35 (S124). The second adjuster 36 calculates a phase PMₜ of the output signal in the power Pᵢₙ of the input signal from the input signal and the feedback signal (S125).

The second adjuster 36 compares an absolute value |PMₜ| of the phase PMₜ of the output signal, which is calculated in step S125, and an absolute value |PM₀| of the phase PM₀ of the output signal, which is acquired from the second adjustment table in the memory 26, with each other (S126). In the comparison, when |PMₜ| is smaller than |PM₀|, it is determined that the phase of the output signal in the AM-PM characteristic is close to 0 and when |PMₜ| is equal to or larger than |PM₀|, it is determined that the phase of the output signal in the AM-PM characteristic is not close to 0.

The second adjuster 36 refers to the second adjustment table in the memory 26 when it is determined that the phase of the output signal in the AM-PM characteristic is close to 0 (“Yes” in S126). In addition, the second adjuster 36 updates the phase PM₀ of the output signal depending on the power Pᵢₙ of the input signal to the phase PMₜ of the output signal, which is calculated in step S125. Further, the second adjuster 36 updates the PA phase and the CA phase depending on the power Pᵢₙ of the input signal to the phases of the first and second signals which are changed in step S124 (S127).

Meanwhile, the second adjuster 36 advances the processing to step S128 without updating the second adjustment table in the memory 26 when it is determined that the phase of the output signal in the AM-PM characteristic is not close to 0 (“No” in S126).

When it is determined that the input signal of the time t=tₘₐₓ is not input with respect to the amplification device 10 (“No” in S128), the time t is incremented by 1 (S129) and the processing of each of steps S122 to S128 is repeatedly executed. Herein, tₘₐₓ represents the maximum value of the predetermined time t.

When it is determined that the input signal of the time t=tₘₐₓ is input with respect to the amplification device 10 (“Yes” in S128), the second adjuster 36 ends the second phase adjustment processing.

As described above, according to the present embodiment, the amplification device 10 is a Doherty type amplification device that amplifies and synthesizes two signals (e.g., the first and second signals) which are split from the input signal. In addition, in the amplification device 10, the first adjuster 35 adjusts the phase difference between two signals by using the power of the output signal, which is acquired by synthesizing two signals. Further, the second adjuster 36 adjusts the phases of two signals by using the AM-PM characteristic indicating the relationship between the power of the input signal and the phase of the output signal while fixing the phase difference adjusted by the first adjuster 35.

By a configuration of the amplification device 10, the phase difference between two signals split from the input signal is appropriately adjusted and further, non-linearity of the AM-PM characteristic regarding the entirety of the Doherty type amplification device may be reduced. As a result, amplification efficiency of the Doherty type amplification device, which is changed depending on the phase difference between two signals, may be improved and further, distortion of the output signal may be suppressed.

In the amplification device 10, the second adjuster 36 adjusts the phases (e.g., the phases of the first and second signals) of two signals so that the phase of the output signal in the AM-PM characteristic is close to the predetermined value (e.g., 0).

By the configuration of the amplification device 10, the AM-PM characteristic may be planarized to further suppress the distortion of the output signal.

### Second Embodiment

The second embodiment relates to variation of second phase adjustment processing. Further, since a basic configuration of an amplification device 10 according to the second embodiment is the same as that of the amplification device 10 according to the first embodiment, the basic configuration of the amplification device 10 according to the second embodiment is described with reference to FIG. 1.

In the amplification device 10 according to the second embodiment, the second adjuster 36 performs the second phase adjustment processing by controlling the phase shifters 14 and 15 after the first phase adjustment processing is performed. That is, the second adjuster 36 adjusts the phases of the first and second signals by using the AM-PM characteristic indicating the relationship between the power of the input signal and the phase of the output signal while fixing the phase difference between the first and second signals, which is adjusted by the first adjuster 35. For example, the second adjuster 36 generates a primary interpolation function passing through two points which exist in an area (hereinafter, referred to as “low-power area”) in which the power of the input signal in the AM-PM characteristic is relatively low by referring to the second adjustment table in the memory 26. In respect to an area (hereinafter, referred to as “high-power area”) in which the power of the input signal in the AM-PM characteristic is relatively high, the second adjuster 36 adjusts the CA phase and the PA phase so that the phase of the output signal depending on points which exist in the high-power area is close to the phase of the output signal based on the primary interpolation function.

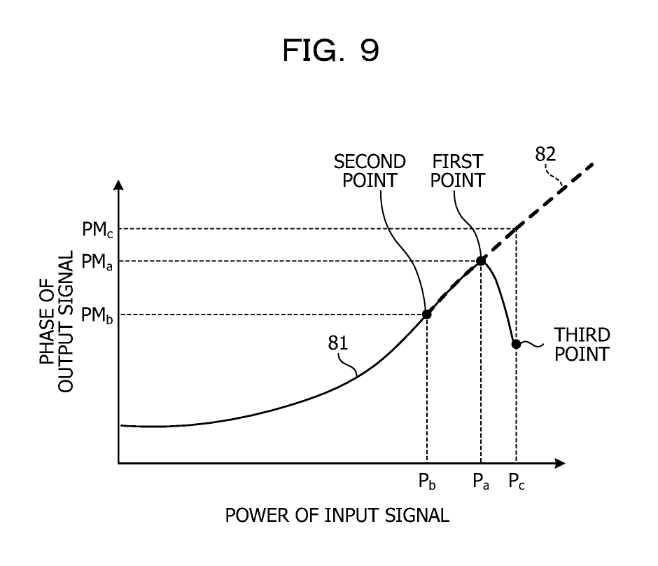

FIG. 9 is a diagram illustrating a detailed example of second phase adjustment processing according to the second embodiment. In FIG. 9, the AM-PM characteristic indicating the relationship between the power of the input signal and the phase of the output signal is expressed by a curved line 81. Further, in FIG. 9, the primary interpolation function passing through two points which exist in the low-power area of the AM-PM characteristic is expressed by a straight line 82. Herein, two points which exist in the low-power area of the AM-PM characteristic include a first point which is a point where a sign of a gradient of the AM-PM characteristic is inverted and a second point which is a point where the power of the input signal is lower than that of the first point in the AM-PM characteristic. As illustrated in FIG. 9, the second adjuster 36 generates, for example, the primary interpolation function (straight line 82) passing through the first and second points which exist in the low-power area of the AM-PM characteristic. The primary interpolation function is generated, for example, by Equation (1) given below.

y={(PM_{b}−PMₐ)/(P_{b}−Pₐ)}·(x−Pₐ)+PMₐ (1)

wherein, x represents the power of the input signal, y represents the phase of the output signal, Pₐ represents the power of the input signal depending on the first point, P_{b} represents the power of the input signal depending on the second point, PMₐ represents the phase of the output signal depending on the first point, and PM_{b} represents the phase of the output signal depending on the second point.

The second adjuster 36 adjusts the phases of the first and second signals so that the phase of the output signal depending on a third point which exists in the high-power area is close to PM_{c} which is the phase of the output signal based on the primary interpolation function (straight line 82), with respect to the high-power area of the AM-PM characteristic.

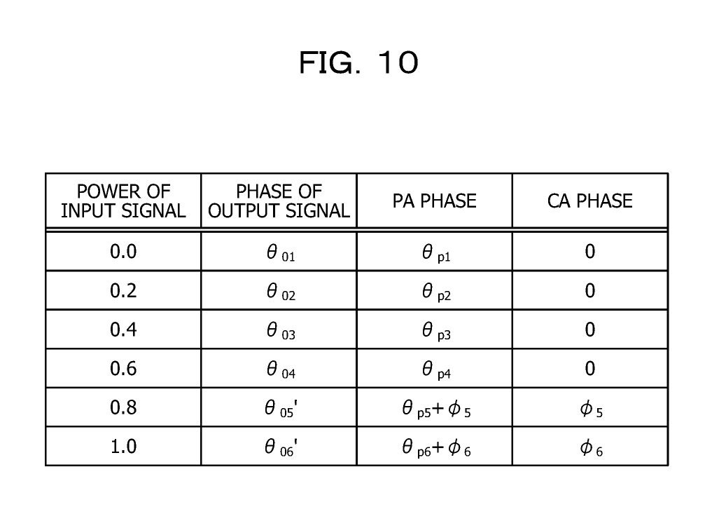

FIG. 10 is a diagram illustrating one example of a second adjustment table after the second phase adjustment processing is performed according to the second embodiment. Herein, the first phase adjustment processing is performed, and as a result, the PA phase is changed to θₚ₁ to θₚ₆ with respect to the power of each input signal (see FIG. 3). In other words, the first phase adjustment processing is performed, and as a result, the phase difference between the first signal and the second signal is changed to θₚ₁ to θₚ₆ so as to maximize the power of the output signal to the power of each input signal. The first phase adjustment processing is performed and thereafter, the second phase adjustment processing is performed. That is, while the phase difference between the first signal and the second signal is fixed to θₚ₁ to θₚ₆, the phases of the first and second signals are adjusted so that the phase of the output signal depending on the point which exists in the high-power area of the AM-PM characteristic is close to the phase of the output signal based on the primary interpolation function. Herein, it is assumed that two points include a point of 0.8 which is the power of the input signal and a point of 0.1 which is the power of the input signal exist in the high-power area of the AM-PM characteristic. Then, as illustrated in FIG. 10, while the phase difference between the first signal and the second signal is fixed to θₚ₅ and θₚ₆, the PA phase and the CA phase are adjusted as large as φ₆ with respect to 0.8 which is the power of the input signal, and the PA phase and the CA phase are adjusted as large as φ₆ with respect to 1.0 which is the power of the input signal.

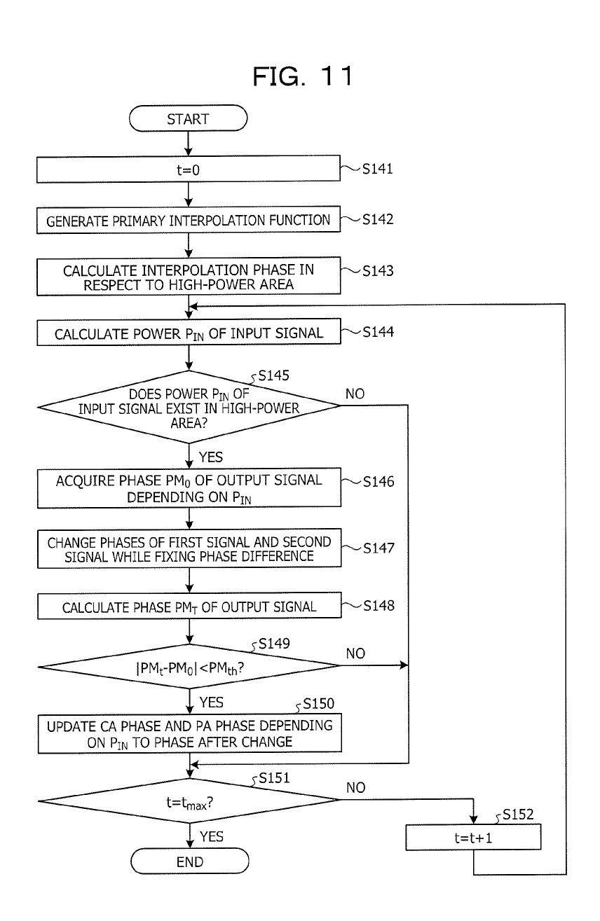

Next, the second phase adjustment processing in the amplification device 10 configured as such will be exemplified in detail with reference to FIG. 11. Further, since the first phase adjustment processing according to the second embodiment is the same as the first phase adjustment processing illustrated in FIG. 7, the description thereof will be omitted herein.

FIG. 11 is a flowchart illustrating one example of the second phase adjustment processing according to the second embodiment. The second phase adjustment processing illustrated in FIG. 11 is executed primarily by the second adjuster 36 after the first phase adjustment processing illustrated in FIG. 7 is performed. Further, it is assumed that the first phase adjustment processing illustrated in FIG. 7 is performed, and as a result, the phase of the output signal when the power Pₒᵤₜ of the output signal to the power Pᵢₙ of the input signal becomes the maximum and the PA phase are stored in the second adjustment table in the memory 26.

As illustrated in FIG. 11, when the input signal of the time t=0 is input with respect to the amplification device 10 (S141), the second adjuster 36 generates the primary interpolation function passing through two points which exist in the low-power area of the AM-PM characteristic by referring to the second adjustment table in the memory 26 (S142). The second adjuster 36 calculates the phase (hereinafter, referred to as “interpolation phase”) of the output signal based on the primary interpolation function in respect to the high-power area of the AM-PM characteristic (S413). Herein, two points which exist in the low-power area of the AM-PM characteristic include a first point which is a point where a sign of a gradient of the AM-PM characteristic is inverted and a second point which is a point where the power of the input signal is lower than that of the first point in the AM-PM characteristic. The interpolation phase calculated by the second adjuster 36 is stored in the second adjustment table in the memory 26 as the phase PM₀ of the output signal depending on the power of the input signal which exists in the high-power area.

When the interpolation phase is calculated, the power Pᵢₙ of the input signal is calculated by the power calculator 11 (S144).

The second adjuster 36 determines whether the power Pᵢₙ of the input signal exists in the high-power area (S145). That is, when the power Pᵢₙ of the input signal is larger than the power of the input signal depending on the first point, the second adjuster 36 determines that the power Pᵢₙ of the input signal exists in the high-power area. When it is determined that the power Pᵢₙ of the input signal does not exist in the high-power area (“No” in S145), the second adjuster 36 advances the processing to step S151.

Meanwhile, when it is determined that the power Pᵢₙ of the input signal exists in the high-power area (“Yes” in S145), the second adjuster 36 acquires the phase PM₀ of the output signal depending on the power Pᵢₙ of the input signal by referring to the second adjustment table in the memory 26 (S146). Since the power Pᵢₙ of the input signal exists in the high-power area, the interpolation phase calculated in step S143 is stored in the second adjustment table in the memory 26 as the phase PM₀ of the output signal.

The second adjuster 36 changes the phases of the first and second signals by controlling the phase shifters 14 and 15 while fixing the phase difference between the first and second signals, which is adjusted by the first adjuster 35 (S147). The second adjuster 36 calculates the phase PMₜ of the output signal in the power Pᵢₙ of the input signal from the input signal and the feedback signal (S148).

The second adjuster 36 determines whether |PMₜ|−PM₀| which is the absolute value of a difference between PMₜ and PM₀ is smaller than a predetermined threshold value PMₜₕ (S149). Herein, when the absolute value |PMₜ−PM₀| is smaller than the threshold value PMₜₕ, it is determined that the phase PMₜ of the output signal is close to the phase PM₀ (that is, the interpolation phase) of the output signal. Meanwhile, when the absolute value |PMₜ−PM₀| is equal to or larger than the threshold value PMₜₕ, it is determined that the phase PMₜ of the output signal is not close to the phase PM₀ (i.e., the interpolation phase) of the output signal.

The second adjuster 36 refers to the second adjustment table in the memory 26 when it is determined that the phase PMₜ of the output signal is close to the phase PM₀ (i.e., the interpolation phase) of the output signal (“Yes” in S149). Further, the second adjuster 36 updates the PA phase and the CA phase depending on the power Pᵢₙ of the input signal to the phases of the first and second signals which are changed in step S147 (S150).

Meanwhile, the second adjuster 36 advances the processing to step S151 without updating the second adjustment table in the memory 26 when it is determined that the phase PMₜ of the output signal is not close to the phase PM₀ (i.e., the interpolation phase) of the output signal (“No” in S149).

When it is determined that the input signal of the time t=tₘₐₓ is not input with respect to the amplification device 10 (“No” in S151), the time t is incremented by 1 (S152) and the processing of each of steps S144 to S150 is repeatedly executed. Herein, tₘₐₓ represents the maximum value of the predetermined time t.

When it is determined that the input signal of the time t=tₘₐₓ is input with respect to the amplification device 10 (“Yes” in S151), the second adjuster 36 ends the second phase adjustment processing.

As described above, according to the present embodiment, in the amplification device 10, the second adjuster 36 generates the primary interpolation function passing through two points which exist in the low-power area of the AM-PM characteristic. In addition, the second adjuster 36 adjusts the phases (e.g., the phases of the first and second signals) of two signals so that the phase of the output signal depending on the point which exists in the high-power area is close to the phase of the output signal based on the primary interpolation function, in respect to the high-power area of the AM-PM characteristic.

By the configuration of the amplification device 10, the linearity of the high-power area of the AM-PM characteristic may be enhanced to further suppress the distortion of the output signal. Further, since the phase is adjusted in respect to only the high-power area of the AM-PM characteristic, a throughput depending on the phase adjustment may be reduced.

### Third Embodiment

The third embodiment relates to variation of second phase adjustment processing. Further, since the basic configuration of an amplification device 10 according to the third embodiment is the same as that of the amplification device 10 according to the first embodiment, the basic configuration of the amplification device 10 according to the third embodiment is described with reference to FIG. 1.

In the amplification device 10 according to the third embodiment, the second adjuster 36 performs the second phase adjustment processing by controlling phase shifters 14 and 15 after first phase adjustment processing is performed. That is, the second adjuster 36 adjusts the phases of the first and second signals by using the AM-PM characteristic indicating the relationship between the power of the input signal and an average value of the phase of the output signal while fixing the phase difference between the first and second signals, which is adjusted by the first adjuster 35.

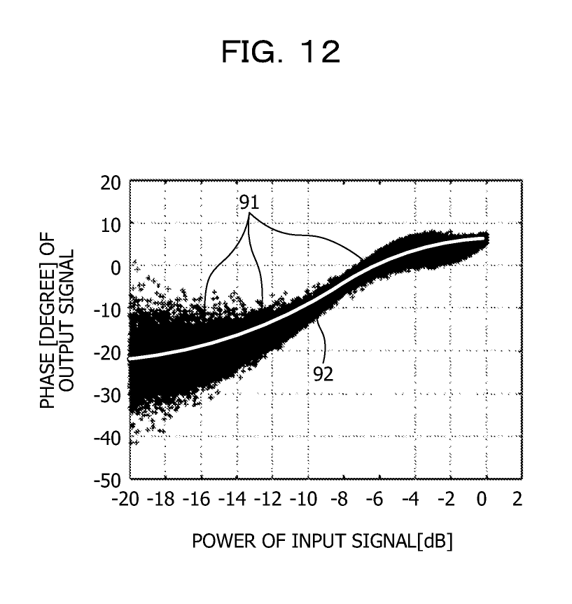

FIG. 12 is a diagram illustrating a detailed example of second phase adjustment processing according to a third embodiment. In FIG. 12, the relationship between the power of the input signal and the phase of the output signal is expressed by a plot group 91. The phase of the output signal to the power of the input signal may vary by a memory effect or an influence of noise in the amplification device 10 as shown in the plot group 91. When the phase of the output signal to the power of the input signal varies, the second adjuster 36 acquires the average value of the phase of the output signal for every power of the input signal to calculate the AM-PM characteristic (curved line 92) indicating the relationship between the power of the input signal and the average value of the phase of the output signal. In addition, the second adjuster 36 adjusts the phases of the first and second signals by using the AM-PM characteristic (curved line 92) while fixing the phase difference between the first signal and the second signal.

As described above, according to the embodiment, in the amplification device 10, the second adjuster 36 adjusts the phases of the first and second signals by using the AM-PM characteristic indicating the relationship between the power of the input signal and the average value of the phase of the output signal.

By the configuration of the amplification device 10, even when the phase of the output signal varies by the memory effect or the influence of the noise in the amplification device 10, the amplification efficiency of the Doherty type amplification device may be improved and further, the distortion of the output signal may be suppressed.

### Fourth Embodiment

A fourth embodiment relates to variation of second phase adjustment processing.

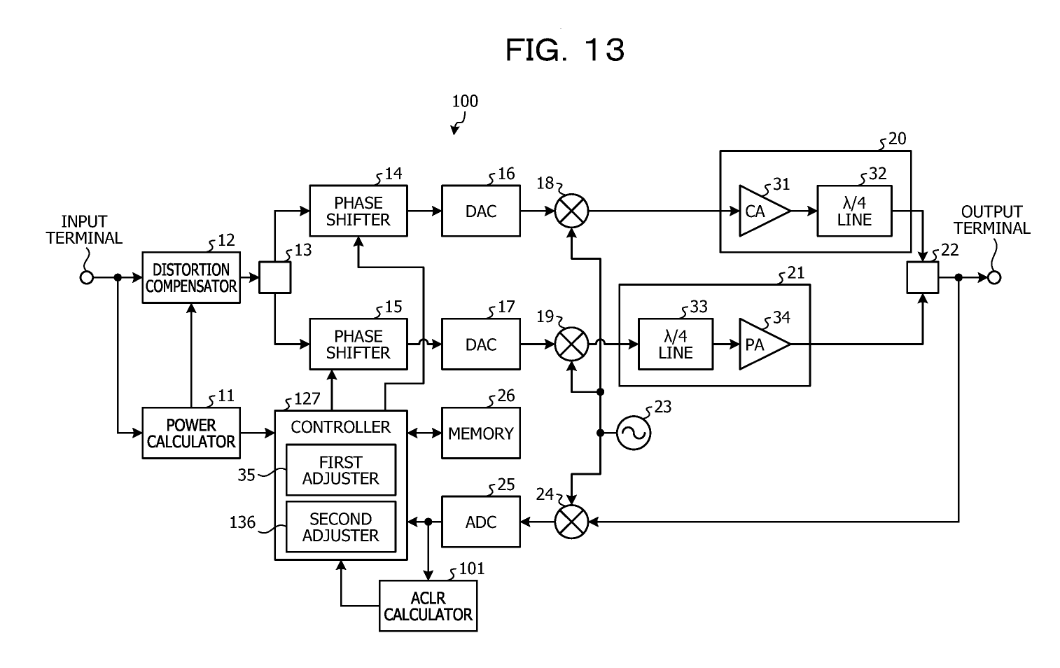

FIG. 13 is a block diagram illustrating a configuration of an amplification device 100 according to a fourth embodiment. As illustrated in FIG. 13, the amplification device 100 includes an adjacent channel leakage ratio (ACLR) calculator 101 and a controller 127. The controller 127 includes a first adjuster 35 and a second adjuster 136.

The ACLR calculator 101 calculates ACLR of the output signal output to the controller 127 from the ADC 25. For example, fast Fourier transform (FFT) is used for calculating the ACLR of the output signal. The ACLR calculator 101 outputs the calculated ACLR of the output signal to the controller 127.

The second adjuster 136 performs the second phase adjustment processing by controlling the phase shifters 14 and 15 after the first phase adjustment processing is performed. That is, the second adjuster 136 adjusts the phases of the first and second signals by using the ACLR of the output signal while fixing the phase difference between the first and second signals, which is adjusted by the first adjuster 35.

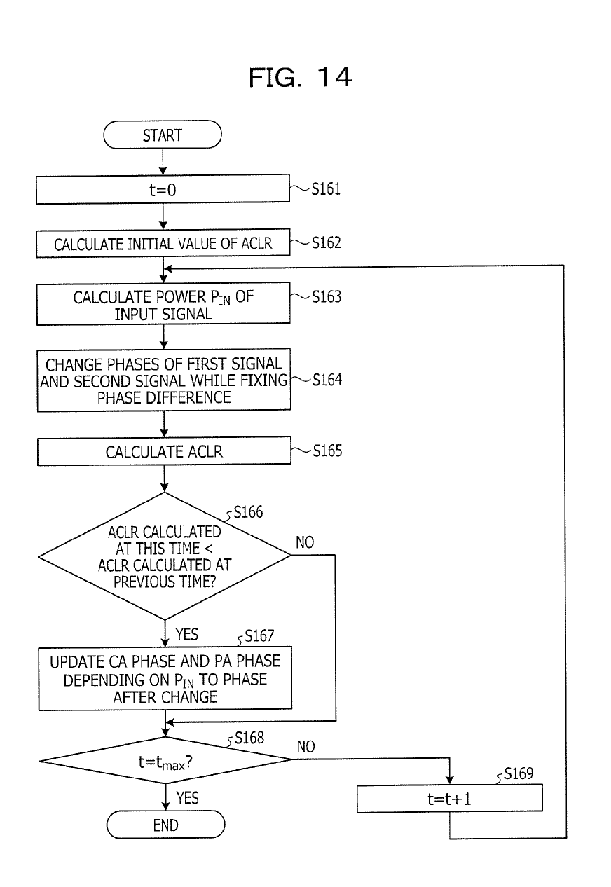

Next, the second phase adjustment processing in the amplification device 100 configured as such will be exemplified in detail with reference to FIG. 14. Further, since the first phase adjustment processing according to the fourth embodiment is the same as the first phase adjustment processing illustrated in FIG. 7, the description thereof will be omitted herein.

FIG. 14 is a flowchart illustrating one example of second phase adjustment processing according to the fourth embodiment. The second phase adjustment processing illustrated in FIG. 14 is executed primarily by the second adjuster 136 after the first phase adjustment processing illustrated in FIG. 7 is performed. Further, it is assumed that the first phase adjustment processing illustrated in FIG. 7 is performed, and as a result, the phase of the output signal when the power Pₒᵤₜ of the output signal to the power Pᵢₙ of the input signal becomes the maximum and the PA phase are stored in the second adjustment table in the memory 26.

As illustrated in FIG. 14, when the input signal of the time t=0 is input with respect to the amplification device 100 (S161), an initial value of the ACLR of the output signal is calculated by the ACLR calculator 101 (S162) and the power Pᵢₙ of the input signal is calculated by the power calculator 11 (S163).

The second adjuster 136 changes the phases of the first and second signals by controlling the phase shifters 14 and 15 while fixing the phase difference between the first and second signals, which is adjusted by the first adjuster 35 (S164). When the phases of the first and second signals are changed, the ACLR calculator 101 calculates the ACLR of the output signal (S165).

The second adjuster 136 determines whether the ACLR of the output signal, which is calculated at this time in step S165, is smaller than the ACLR of the output signal, which is calculated at the previous time (S166). Herein, the ACLR of the output signal, which is calculated at the previous time, is the initial value of the ACLR of the output signal, which is calculated at the previous time in step S165, or the ACLR of the output signal, which is calculated in step S162.

The second adjuster 136 refers to the second adjustment table in the memory 26 when it is determined that the ACLR of the output signal, which is calculated at this time, is smaller than the ACLR of the output signal, which is calculated at the previous time (“Yes” in S166). Further, the second adjuster 136 updates the PA phase and the CA phase depending on the power Pᵢₙ of the input signal to the phases of the first and second signals which are changed in step S164 (S167).

Meanwhile, the second adjuster 136 advances the processing to step S168 without updating the second adjustment table in the memory 26 when it is determined that the ACLR of the output signal, which is calculated at this time, is equal to or larger than the ACLR of the output signal, which is calculated at the previous time (“No” in S166).

When it is determined that the input signal of the time t=tₘₐₓ is not input with respect to the amplification device 100 (“No” in S168), the time t is incremented by 1 (S169) and the processing of each of steps S163 to S167 is repeatedly executed. Herein, tₘₐₓ represents the maximum value of the predetermined time t.

When it is determined that the input signal of the time t=tₘₐₓ is input with respect to the amplification device 100 (“Yes” in S168), the second adjuster 136 ends the second phase adjustment processing.

As described above, according to the embodiment, in the amplification device 100, the second adjuster 136 adjusts the phases (i.e., the phases of the first and second signals) of two signals by using the ACLR of the output signal while fixing the phase difference adjusted by the first adjuster 35.

By the configuration of the amplification device 100, the ACLR of the output signal may be improved to further suppress the distortion of the output signal.

### Other Embodiments

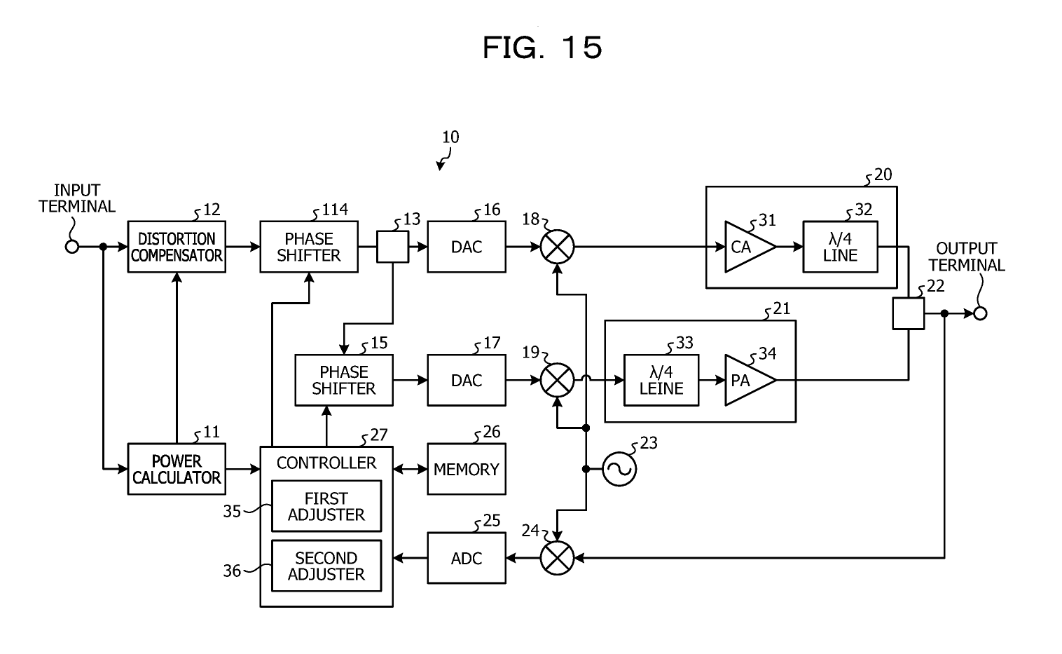

(1) In the first embodiment, the example in which the second adjuster 36 performs the second phase adjustment processing by controlling the phase shifter 14 installed in the system of the amplifier 20 and the phase shifter 15 installed in the system of the amplifier 21 is described, but the disclosed technology is not limited thereto. For example, the second adjuster 36 may perform the second phase adjustment processing by controlling the phase shifter 114 installed between the distortion compensator 12 and the signal splitter 13 as illustrated in FIG. 15. In this case, the phase shifter 14 is omitted and the phase shifter 15 installed in the system of the amplifier 21 is applied to the first phase adjustment processing. FIG. 15 is a block diagram illustrating a configuration of an amplification device 10 according to a modified example.

(2) The power calculator 11, the distortion compensator 12, the controller 27, the first adjuster 35, the second adjuster 36, the ACLR calculator 101, the controller 127, and the second adjuster 136 as hardware are implemented by, for example, a processor. One example of the processor may include a central processing unit (CPU), a digital signal processor (DSP), a field programmable gate array (FPGA), and the like. Further, the memory 26 as the hardware is implemented by, for example, a random access memory (RAM) such as a synchronous dynamic random access memory (SDRAM), or the like, a read only memory (ROM), or a flash memory. Further, the signal splitter 13, the phase shifters 14 and 15, the DACs 16 and 17, the frequency converters 18, 19, and 24, the amplifiers 20 and 21, the synthesizer 22, and the ADC 25 are implemented by, for example, an analog circuit.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. An amplification device that amplifies two signals split from an input signal and synthesizes the amplified signals, the amplification device comprising:
a first adjuster that adjusts a phase difference between the two signals by using power of an output signal acquired by synthesizing the two signals; and
a second adjuster that adjusts phases of the two signals by using an Amplitude Modulation (AM)-Phase Modulation (PM) characteristic that indicates a relationship between the power of the input signal and the phase of the output signal in a state of fixing the phase difference adjusted by the first adjuster.

2. The amplification device according to claim 1, wherein the second adjuster adjusts the phases of the two signals so that the phase of the output signal in the AM-PM characteristic is close to a predetermined value.

3. The amplification device according to claim 1, wherein the second adjuster generates an interpolation function passing through two points that exist in a first area having a relatively low power of the input signal in the AM-PM characteristic, and
adjusts the phases of the two signals so that the phase of the output signal depending on a point that exists in a second area is close to the phase of the output signal based on the interpolation function in respect to the second area having a relatively high power of the input signal in the AM-PM characteristic.

4. The amplification device according to claim 1, wherein the second adjuster adjusts the phases of the two signals by using the AM-PM characteristic indicating the relationship between the power of the input signal and an average value of the phase of the output signal.

5. The amplification device according to claim 1, wherein the second adjuster adjusts the phases of the two signals by using an adjacent channel leakage power ratio of the output signal in a state of fixing the phase difference adjusted by the first adjuster.

6. A method of amplifying a signal, the method comprising:
splitting, by a signal splitter, an input signal into two signals;
adjusting, by a first adjuster, a phase difference between the two signals by using power of an output signal acquired by synthesizing the two signals;
adjusting, by a second adjuster, phases of the two signals by using an Amplitude Modulation (AM)-Phase Modulation (PM) characteristic that indicates a relationship between the power of the input signal and the phase of the output signal in a state of fixing the phase difference adjusted by the first adjuster;
amplifying the two signals; and
synthesizing the two signals.
